(19) United States
(12) Patent Application Publication
(10) Pub. No.: US 2024/0373585 A1
(43) Pub. Date: Nov. 7, 2024

(54) GSGDG 7154 Computer System

(71) Applicant: Abdul Luke Gomez, San Diego, CA (US)

(72) Inventor: Abdul Luke Gomez, San Diego, CA (US)

(21) Appl. No.: 18/313,340

(22) Filed: May 7, 2023

(51) Int. Cl. H05K 7/20

(52) U.S. Cl. CPC H05K 7/20254; H05K 7/20272

(57) ABSTRACT

A computer system consisting of the following components: a refrigerated circuit board. a refrigerated electrical bank, an insulated housing unit. an insulated front unit cover, a dual temperature conduit pump, a dual temperature conduit, an optional adaptive heat sink and refrigerated circuit board heat sink, and a digital readout display.

### BACKGROUND

### 1. Field of the Invention

The present invention relates generally to computers and more specifically it relates to a novel computer system that changes and redefines the form factors across the computer hardware components that is enabled by a novel embedded cooling system, eliminating heat, and allowing for footprint minimization and up to 60% waste reduction across the board.

### 2. Description of the Related Art

Any discussion of the prior art throughout the specification should in no way be considered as an admission that such prior art is widely known or forms part of common general knowledge in the field.

“Thermal management” denotes the array of problem-solving design tools and material technologies applied to regulate the unwanted heat caused by the normal functioning of an electronic system. Every technological development in the semiconductor, microprocessor and computer industries correlates to a corresponding increase in the operating heat generated by the system. Fans are extensively utilized to cool modern IT equipment, as are liquid cooling systems.

A prior art example upon which this current concept builds is that of All-in-One (AIO) liquid coolers. These generally constitute a waterblock, two hoses that cycle the coolant, and a radiator. The limitations of this art are the fact that it focuses on piecemeal, central processing unit (CPU) component-related heat sinks instead of eliminating the heat at the source of all components in conjunction with the adaptive conduits and sinks. AIA coolers are also too complex for novice or even intermediately experienced computer aficionados to install or maintain.

The GSGDG 7154 Computer System consists of a refrigerated circuit board, a refrigerated electrical bank, an insulated housing unit, adaptive heat sinks, a dual temperature conduit pump, and a dual temperature conduit to entirely eliminate heat at the refrigerated circuit board source, providing a comprehensive full board cooling and moisture encasing ability, eliminating wires, and further enhancing the duration and effectiveness of cooling due to the full encapsulation provided. The refrigerated electrical bank can be manufactured with a conventional pump and/or with a novel dual temperature conduit pump to cycle liquid and eliminate heat from the system. The dual temperature conduit pump circulates coolant in different layers and the coolant can be returned using an insulated or uninsulated conduit depending on the use case.

The GSGDG 7154 Computer System provides a wide variety of options to computer hardware manufacturers including but not limited to the following applications: the ability to create smaller computers, with attendant space saving, material saving and mobility benefits on all form factors; the option of re-engineering all CPUs, Graphics Processing Units (GPUs) and related units with this new solution using the GSGDG and/or its components; the creation of more powerful personal computers (PCs) in a smaller form factor; the creation of more powerful individual components due to the GSGDG heat control and heat elimination capability.

The GSGDG 7154 Computer System provides a wide variety of options to consumers including but not limited to the following applications: the option to purchase smaller computers, with attendant space saving, material saving and mobility benefits; enablement of novice computer aficionados to assemble and maintain their computer systems; 90% reduction of the heat footprint of conventional units; ability to retrofit the GSGDG 7154 Computer System into existing cooling systems.

In these respects, the GSGDG 7154 Computer System according to the present invention substantially departs from the conventional concepts and designs of the prior art, while introducing novel components such as the dual temperature conduit pump and a dual temperature conduit, and in so doing provides a system primarily developed for the purpose of system cooling, eliminating wiring, and enabling computer manufacturers to make smaller, more powerful PCs.

### BRIEF SUMMARY OF THE INVENTION.

In view of the foregoing disadvantages inherent in the known types of CPU cooling devices in the prior art, the present invention provides a new computer system wherein the same can be utilized for hardware cooling, eliminating wiring, and enabling computers to be built smaller. The general purpose of the present invention, which will be described subsequently in greater detail, redefines, improves and overhauls prior art computer systems and embodies many novel features that result in a new computer system which is not anticipated, rendered obvious, suggested, or even implied by any of the prior art computer utility patents, either alone or in any combination thereof.

To attain this, the present invention generally comprises the following components: a refrigerated circuit board, a refrigerated electrical bank, an insulated housing unit, adaptive heat sinks, a dual temperature conduit pump, and a dual temperature conduit.

There has thus been outlined, rather broadly, the more important features of the invention in order that the detailed description thereof may be better understood, and in order that the present contribution to the art may be better appreciated. There are additional features of the invention that will be described hereinafter and that will form the subject matter of the claims appended hereto.

In this respect, before explaining at least one embodiment of the invention in detail, it is to be understood that the invention is not limited in its application to the details of construction and to the arrangements of the components set forth in the following description or illustrated in the drawings. The invention is capable of other embodiments and of being practiced and carried out in various ways. Also, it is to be understood that the phraseology and terminology employed herein are for the purpose of the description and should not be regarded as limiting.

A primary object of the present invention is to provide a computer system that will overcome the shortcomings of the prior art liquid cooling systems, changing computer system design, form factor and functionality.

A second object is to eliminate wiring present in computers.

A third object is to eliminate humidity, which is accomplished through the insulated housing unit.

A further object is to enable computers to be built smaller, with attendant space saving, material saving and mobility benefits on all form factors.

An additional object is to enable the creation of more powerful computers in a smaller form factor.

Another object is to facilitate the creation of more powerful individual computer components due to the GSGDG 7154 Computer System's heat elimination capability.

Another object is to enable novice computer aficionados to assemble and maintain their computer systems with ease given the absence of wires.

A further object is the ability to retrofit the GSGDG 7154 Computer System into existing cooling systems. Another object is to improve upon underperforming conventional pumps through the optional use of a dual temperature conduit pump, which drastically changes the temperature, looping back coolant through a single conduit and can be reversed to supply different temperatures of coolant based on user preference.

A further object is to render existing failed or failing systems operational, as the GSGDG 7154 Computer System can be connected to them in order to render them operational through the use of this invention's adaptive conduit siphoning capability. The dual temperature conduit pump can also be used independently to cool an existing system.

Another object is to provide a computer system that supports waste reduction and consumer environmental stewardship when compared to the prior art.

Other objects and advantages of the present invention will become obvious to the reader and it is intended that these objects and advantages are within the scope of the present invention.

To the accomplishment of the above and related objects, this invention may be embodied in the form illustrated in the accompanying drawings, attention being called to the fact, however, that the drawings are illustrative only, and that changes may be made in the specific construction illustrated and described within the scope of the appended claims.

### BRIEF DESCRIPTION OF THE SEVERAL VIEWS OF THE DRAWINGS

Various other objects, features and attendant advantages of the present invention will become fully appreciated as the same becomes better understood when considered in conjunction with the accompanying drawings.

Like reference characters designate the same or similar parts throughout the several views, wherein:

FIG. 1 is a front facing view with side detail of the present invention.

FIG. 2 is a front facing view, with insulated front unit cover removed, of the interior of the present invention showing the adaptive heat sink.

FIG. 3 is a front facing view, with the insulated front unit cover and the adaptive board sink removed, of the interior of the present invention showing the GPU card inserted.

FIG. 4 is a front facing view of the insulated front unit cover of the invention.

FIG. 5 is a back facing view with side detail of the present invention.

FIG. 6 is a back facing view with side detail of the present invention with the ducts removed to illustrate the adaptive potential of the conduit connection points.

FIG. 7 is a semi-transparent front view of the refrigerated circuit board of the present invention, illustrating that the adaptive heat sink can be embedded and go through the board.

FIG. 8 is a semi-transparent zoomed in front view of the refrigerated circuit board of the present invention, illustrating that the adaptive heat sink can be detached from the board.

FIG. 9 is a front view of the refrigerated circuit board of the present invention without the GPU attached.

FIG. 10 is a front view of the refrigerated circuit board of the present invention with a GPU attached, illustrating how a GPU can be inserted into the insulated housing unit.

FIG. 11 is an interior view of the refrigerated circuit board heat sink of the present invention.

FIG. 12 is a front view with side detail of the refrigerated electrical bank heat sink of the present invention.

FIG. 13 is a top view with top cover removed of the present invention.

FIG. 14 is a top view with top cover removed of the refrigerated electrical bank.

FIG. 15 is a zoomed in front view detail of the end of the dual temperature pump conduit, displaying the layered interior that enables insulation, electrical conduction, and coolant circulation across multiple layers within the same conduit.

### DETAILED DESCRIPTION OF THE INVENTION

### A. Overview

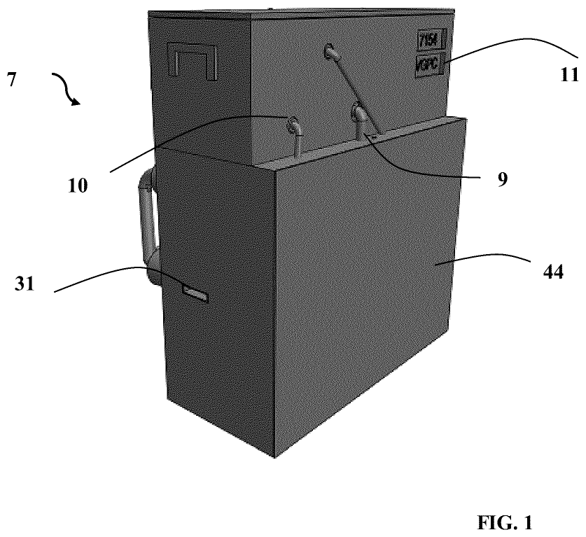

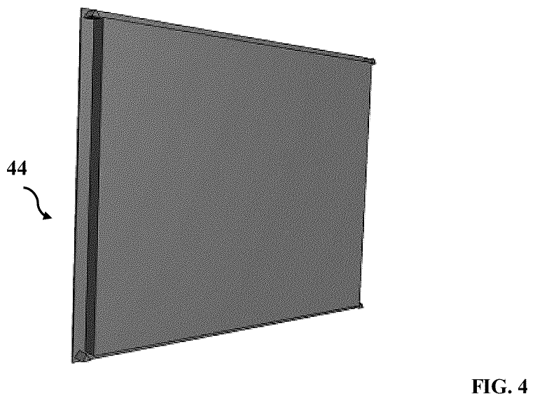

Turning now descriptively to the drawings, in which similar reference characters denote similar elements throughout the several views, FIGS. 1 through 15 illustrate the GSGDG 7154 Computer System 7, which comprises an insulated housing unit 13, a refrigerated circuit board 37, a refrigerated electrical bank 33, a dual temperature conduit pump 22, a dual temperature pump conduit(s) 47, an insulated front unit cover 44, optional heat sinks 3, 45 and a digital readout display 11 that shows the sensor, temperature, voltage and other status elements of all components. The adaptive heat sink 3 and refrigerated circuit board heat sink 45 can be adaptively connected to multiple conduit connection points 5 across the System 7 to achieve heat elimination.

### B. Insulated Housing Unit

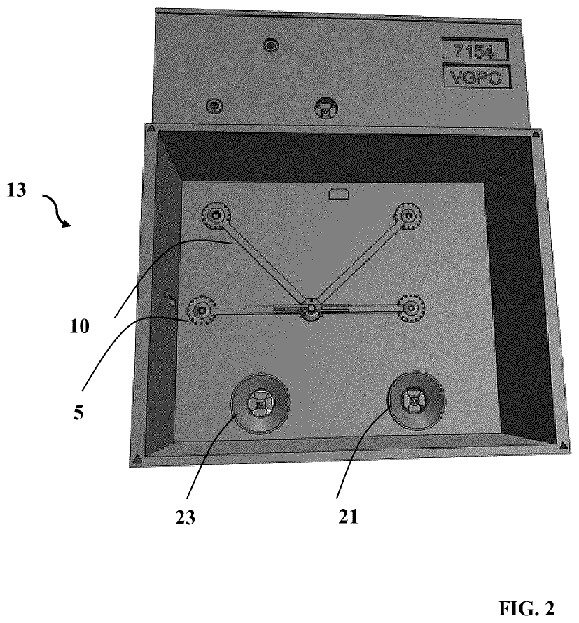

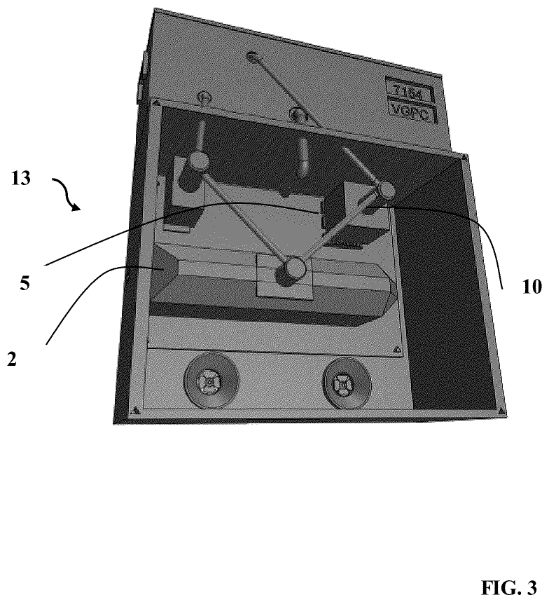

The insulated housing unit 13 is preferably comprised of conduits 10 and conduit connection points 5, which can be of any size, number or shape so that they can adjust to the different types of circuit boards and other hardware to which they might be connected. These items are housed within the insulated housing unit 13 cavity as illustrated in FIG. 2, to allow heat sinks 3, 45 and other components such as the GPU 2 illustrated in FIG. 3. to be adaptably attached to or retrofitted to it.

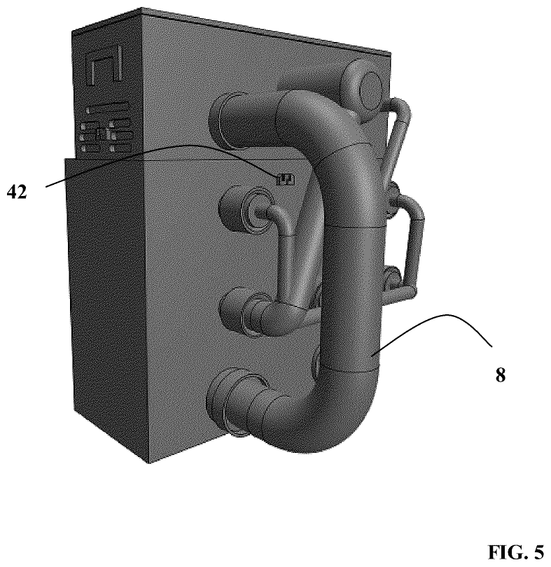

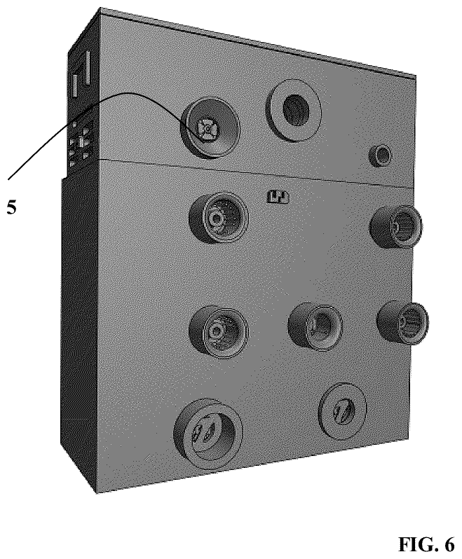

A temperature sensor outlet 23 that helps eliminate exhaust, and that aids in automatic system shutoff in case of moisture, electrical and cooling abnormalities, and a refrigerated fan 21 are also contained within the insulated housing unit 13 cavity for heat elimination. The back of the insulated housing unit 13 includes an input plug 42, an air duct 8 and conduits 10 as illustrated in FIG. 5. The air duct 8 and conduits 10 can be adaptively removed and interchanged through the use of conduit connection points 5 as illustrated in FIG. 6.

### C. Refrigerated Circuit Board

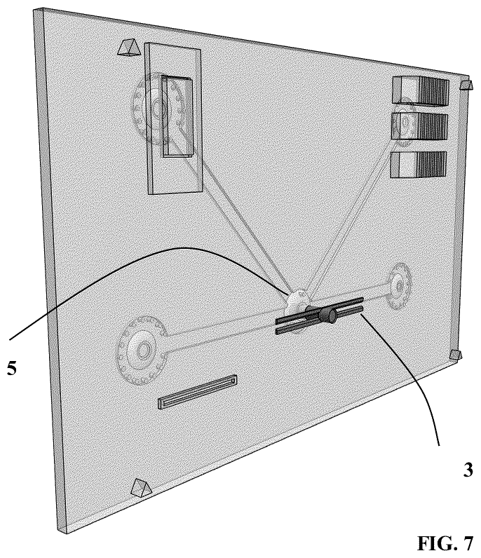

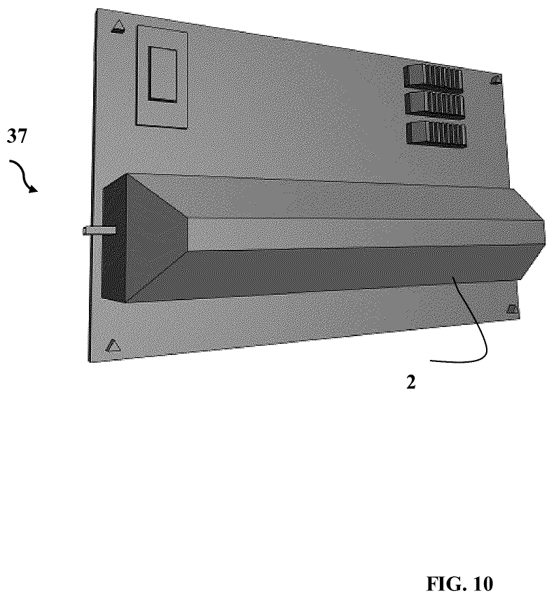

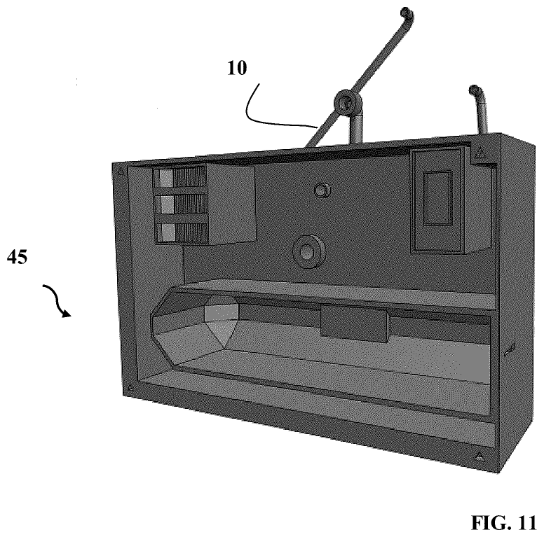

The refrigerated circuit board 13 is preferably comprised of conduit connection points 5 with the option to attach an adaptive heat sink 3, as illustrated in FIG. 7, a GPU 2 as illustrated in FIG. 10, a refrigerated circuit board heat sink to provide extreme heat reduction as illustrated in FIG. 11, or other device. FIG. 7 illustrates how the adaptive heat sink 3 can optionally be embedded in the board. The zoomed in detail view of the refrigerated circuit board 13 in

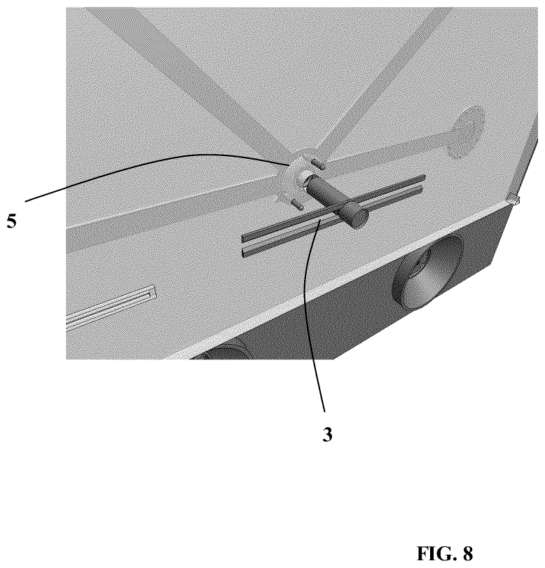

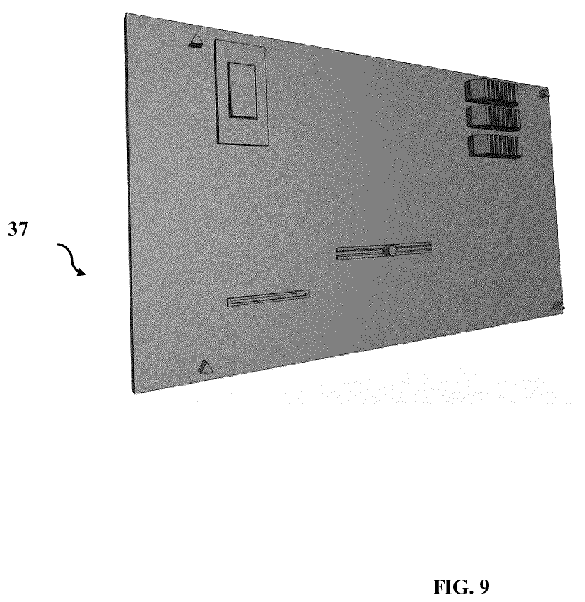

FIG. 8 illustrates how the adaptive heat sink 3 can be optionally detached from the board. As an additional option, even the conduit connection points 5 and conduits 10 can be adaptively detached from the refrigerated circuit board 13 as illustrated in FIG. 9.

### D. Refrigerated Electrical Bank

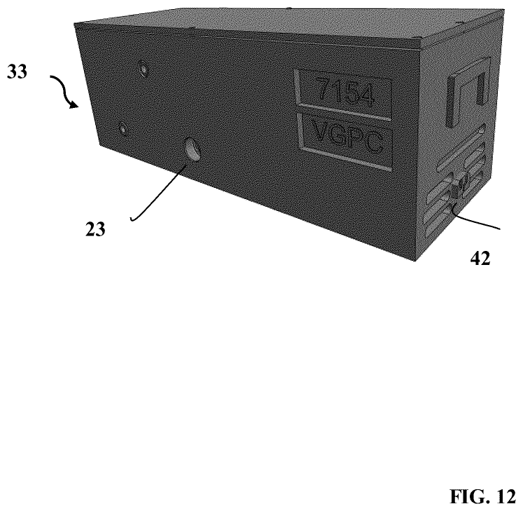

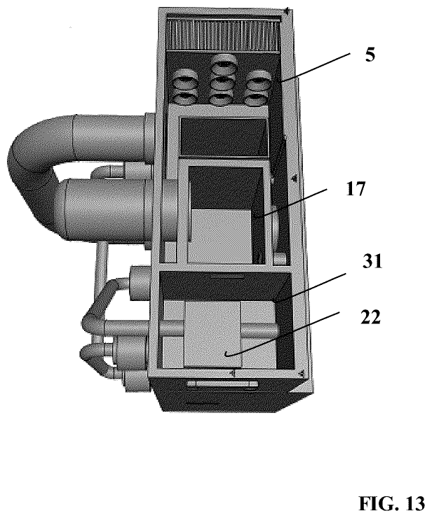

The refrigerated electrical bank 33 is preferably comprised of a temperature sensor outlet 23 and an input plug 42 visible on the exterior surface as illustrated in FIG. 12. Once the top cover is opened, as illustrated in FIG. 13, the internal components of the refrigerated electrical bank 33 such as the refrigerated chamber 17, the liquid pumping chamber 31, the dual temperature conduit pump 22, the a dual temperature pump conduits 47 and the a dual temperature conduit connection points 5 become apparent.

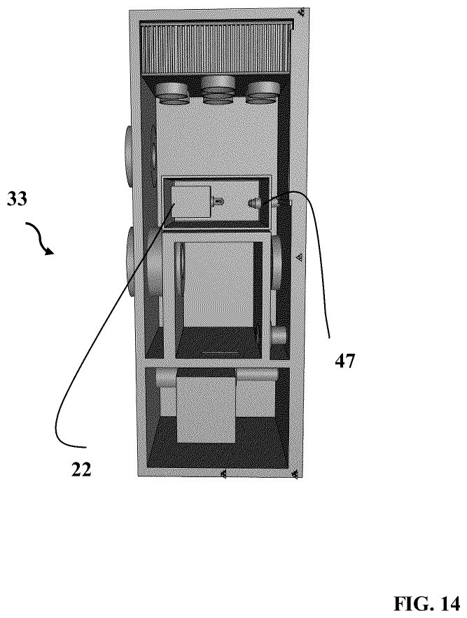

The dual temperature conduit pump 22 cycles liquid and removes unwanted heat from the refrigerated electrical bank 33, while the refrigerated chamber 17 cools the liquid and the liquid pumping chamber 31 houses the dual temperature conduit pump 22 which uses a single pump to circulate coolant through the dual temperature conduit pump conduit 47, siphoning coolant through the outside and insulating the returning coolant as illustrated in FIG. 14. Depending on the user case, the dual temperature pump conduits 47 may or may not be insulated. The dual temperature conduit pump 22 pumps liquid through the conduits illustrated in FIG. 13 and FIG. 5, though it can be detached and replaced with a conventional pump per user preference.

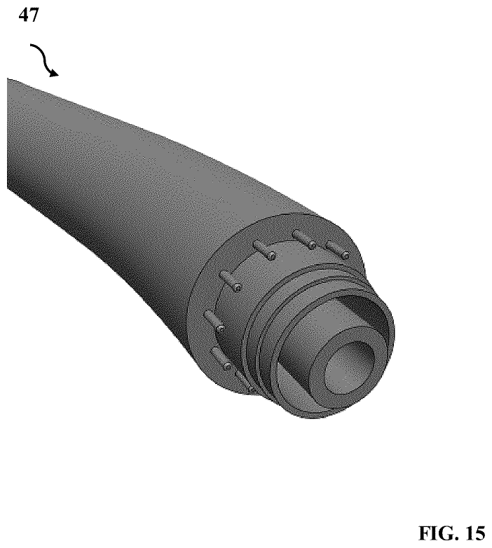

The dual temperature pump conduit 47 is composed of a layered interior that enables insulation, electrical conduction, and coolant circulation across multiple layers within the same conduit as illustrated in FIG. 15.

### E. In Use

In use, the user connects the refrigerated electrical bank 33 to the insulated housing unit 13 through the use of conduits 10 and closes the insulated front unit cover 44 to enclose the unit. The user can connect the GSGDG 7154 Computer System 7 components to their existing computer using the conduit connection points 5 and/or input plug 42.

Within the insulated housing unit 13 cavity, the user can optionally attach the refrigerated circuit board 13, the refrigerated circuit board heat sink 45, and/or the adaptive heat sink 3, in whatever combination is desired depending on the user's heat elimination needs. The refrigerated circuit board heat sink 45 enables complete encapsulation of the refrigerated circuit board 13, thus providing maximum refrigeration to the entire system. The user can obtain information regarding the sensor, temperature, voltage and other status elements of all components via the digital readout display 11. This facilitates the optional shutoff of the computer if status abnormalities are detected.

One of the many possible variations within the scope of the present invention is for a user to retrofit existing computer hardware components onto the GSGDG 7154 computer system 7, using the conduit connection points 5 and/or input plug 42, which enhances usability of the system.

What has been described and illustrated herein is a preferred embodiment of the invention along with some of its variations. The terms, descriptions and figures used herein are set forth by way of illustration only and are not meant as limitations. Those skilled in the art will recognize that many variations are possible within the spirit and scope of the invention, which is intended to be defined by the following claims (and their equivalents) in which all terms are meant in their broadest reasonable sense unless otherwise indicated. Any headings utilized within the description are for convenience only and have no legal or limiting effect.

1. A computer system, comprising:
Hardware components, which include: a circuit board with or without conduits for refrigeration, a refrigerated electrical bank and an insulated housing unit; the circuit board can be completely cooled or specific parts can receive targeted cooling to prevent heat buildup to all of the necessary components. The conduits can deliver electrical power and/or refrigeration. The system's refrigerated electrical bank can be affixed atop the insulated housing unit or be placed in another location of the user's choosing, thus saving space. The refrigerated electrical bank includes a refrigerated chamber, and a liquid pumping chamber as well as exterior air ducts, temperature controlled fans and input plugs, a liquid-circulation assembly for circulation of the liquid coolant through the system and a conventional pump and/or dual temperature conduit pump and dual temperature pump conduits that cycles liquid coolant through the assembly; the insulated housing unit includes insulated conduits that deliver electrical power and refrigeration, that will be manufactured directly into the board or separately stationed in the housing, and includes sensors and digital readout displays. It also includes an additional power supply outlet to accommodate older components and circuit boards that can be powered by external sources if necessary. The insulated housing unit also includes conduits to control temperatures and has an optional refrigerated circuit board heat sink, that encapsulates the entirety of the circuit board for maximum temperature control.

2. The computer system of claim 1, wherein the hardware components and their constituent parts can be independently retrofitted onto existing computer hardware, cooling systems and related devices.

3. The computer system of claim 1, wherein the refrigerated circuit board is completely encapsulated, thus refrigerating the entire system as a whole in a controlled environment.

4. The computer system of claim 1, wherein the hardware components and their constituent parts are connected without the use of wires or screws, thus streamlining usability.

5. The computer system of claim 1, wherein the electrical and coolant conduits are removable, interchangeable and upgradeable.

6. The computer system of claim 1, wherein the refrigerated electrical bank conduit connection points can be connected to different types of heat sinks.

7. The computer system of claim 1, wherein the insulated housing unit is powered through the input plug.

8. The computer system of claim 1, wherein the refrigerated electrical bank, conduit points and its housing, can be sold as a standalone unit and the conduit points can also be retrofitted to or adapted to any existing conduits.

9. The computer system of claim 1, further comprising an array of sensors dedicated to detecting temperature, voltage and other metrics with an automatic shutoff capability in case of sub-optimal moisture, electrical or cooling deviations.

10. The computer system of claim 1, further comprising a display screen that exhibits information derived from external and internal sources including temperature and voltage, and receives input from various sources such as the sensors and the refrigerated circuit board.

11. The computer system of claim 1, wherein the pump and/or dual temperature conduit pump and are removable, interchangeable, and upgradeable.

12. The computer system of claim 1, wherein the dual temperature conduit pump delivers variable temperatures.

13. The computer system of claim 12, wherein a single conduit is used in conjunction with the dual temperature conduit pump to circulate coolant through the system.

14. The computer system of claim 13, wherein the dual temperature pump conduit used in conjunction with the dual temperature conduit pump is composed of a layered interior that enables insulation, electrical conduction, and coolant circulation across multiple layers within a single conduit.

15. The computer system of claim 1, wherein the adaptive heat sink is able to siphon coolant.
